(19) United States
(12) Patent Application Publication
(10) Pub. No.: US 2025/0070579 A1
(43) Pub. Date: Feb. 27, 2025

(54) METHOD FOR CALIBRATING BATTERY LEVEL, ELECTRONIC DEVICE AND STORAGE MEDIUM

(71) Applicant: SHENZHEN PAX SMART NEW TECHNOLOGY CO., LTD., Shenzhen (CN)

(72) Inventors: Chenghe YANG, Shenzhen (CN); Zhihua WU, Shenzhen (CN)

(21) Appl. No.: 18/720,801

(22) PCT Filed: Oct. 18, 2022
(86) PCT No.: PCT/CN2022/125964

§ 371 Date: Jun. 17, 2024

(30) Foreign Application Priority Data
Dec. 17, 2021 (CN) 202111556687.3

(51) Int. Cl. H02J 7/00; G01R 31/3832; G01R 31/3842; G01R 31/388

(52) U.S. Cl. CPC H02J 7/0048; G01R 31/3833; G01R 31/3842; G01R 31/388; H02J 7/0063

(57) ABSTRACT

A method for calibrating a battery level, an electronic device and a storage medium. The method includes steps of: obtaining a turn-off type when the electronic device is last turned off after the electronic device is turned on; and obtaining a current battery level of the electronic device based on turn-off time and a turn-off remaining battery level when the electronic device is last turned off in case that the turn-off type is a first type. The first type includes that the first battery supplies power to the charging management module but not to peripheral circuit module and the coulometer after the electronic device is turned off. Compared with the case in the prior art of the current battery level obtained by using an OCV curve, the current battery level obtained by using the turn-off time and turn-off remaining battery level at the last turn-off is more accurate.

### CROSS-REFERENCE TO RELATED APPLICATIONS

This application is the national phase entry of International Application No. PCT/CN2022/125964, filed on Oct. 18, 2022, which is based upon and claims priority to the Chinese Patent Application No. 202111556687.3, filed on Dec. 17, 2021, the entire contents each of which are incorporated herein by reference.

### TECHNICAL FIELD

The present application relates to the field of battery level calibration technology, and in particular, to a method for calibrating a battery level, an electronic device and a storage medium.

### BACKGROUND

With the development of science and technology, more and more electronic devices are used in people's daily lives. Different electronic devices may have different functions, but today's electronic devices all require power to operate normally.

The power source for many electronic devices is a battery, and the battery supplies power to the electronic device to ensure the normal electricity demand of the electronic device. Currently, in order to ensure the accuracy of the remaining battery level of the electronic device displayed in a coulometer when the coulometer in the electronic device is restarted after a power outage, the battery level of the electronic device needs to be calibrated. At present, the calibration of battery level is mostly carried out through the OCV curve. Since the OCV curve is inaccurate, the calibrated battery level is inaccurate.

### SUMMARY

Embodiments of the present application provide a method for calibrating a battery level, an electronic device and a storage medium, which can solve the problem of inaccurate battery level calibration.

In accordance with a first aspect, an embodiment of the present application provides a method for calibrating a battery level, which is applied to an electronic device. The electronic device includes a first battery, a charging management module, a peripheral circuit module, and a coulometer for monitoring a battery level of the electronic device. The first battery supplies power to the coulometer and the peripheral circuit module through the charging management module after the electronic device is turned on.

The method includes steps of:

Obtaining a turn-off type when the electronic device is last turned off after the electronic device is turned on: and

Obtaining a current battery level of the electronic device based on turn-off time and a turn-off remaining battery level when the electronic device is last turned off in case that the turn-off type is a first type, where the first type includes that the first battery supplies power to the charging management module but not to the peripheral circuit module and the coulometer after the electronic device is turned off.

In accordance with a second aspect, an embodiment of the present application provides an electronic device, which includes: a first battery, a charging management module, a peripheral circuit module, and a coulometer for monitoring a battery level of the electronic device. The first battery supplies power to the coulometer and the peripheral circuit module through the charging management module after the turn-on of the electronic device. The peripheral circuit module includes a processor.

The processor is configured to implement the method for calibrating the battery level described in the first aspect.

In accordance with a third aspect, an embodiment of the present application provides an electronic device, including: a memory, a processor, and a computer program stored in the memory and executable by the processor. The processor, when executing the computer program, is configured to implement the method for calibrating the battery level described in the above first aspect.

In accordance with a fourth aspect, an embodiment of the present application provides a computer-readable storage medium that stores a computer program. The computer program, when executed by a processor, causes the method for calibrating the battery level described in the above first aspect to be implemented.

In accordance with a fifth aspect, an embodiment of the present application provides a computer program product that, when executed on a piece of terminal equipment, enables the terminal equipment to implement the method for calibrating the battery level described in the above first aspect.

Compared with the existing technologies, the embodiment in accordance with the first aspect of the present application has the following beneficial effects: first, the turn-off type when the electronic device is last turned off is obtained after the electronic device is turned on; and then the current battery level of the electronic device is obtained according to the turn-off time and the turn-off remaining battery level when the electronic device is last turned off in case that the turn-off type is the first type. Among them, the first type includes that the first battery supplies power to the charging management module but not to the peripheral circuit module and coulometer after the electronic device is turned off. In the present application, the current battery level is obtained by using the turn-off time and the turn-off remaining battery level at the last turn-off, which is more accurate than the current battery level obtained by using the OCV curve in the existing technologies.

It can be understood that, for beneficial effects of the above second to fifth aspects, references may be made to the relevant descriptions in the above first aspect, which will not be described again here.

### BRIEF DESCRIPTION OF DRAWINGS

In order to illustrate the technical schemes in the embodiments of the present application more clearly, the drawings that need to be used in the description of the embodiments will be briefly introduced below. Obviously, the drawings in the following description are merely some embodiments of the present application. For persons of ordinary skills in the art, other drawings may be obtained based on these drawings without exerting creative efforts.

FIG. 1 is a schematic structural diagram of an electronic device provided by an embodiment of the present application:

FIG. 2 is a schematic flowchart of a method for calibrating a battery level provided by an embodiment of the present application:

FIG. 3 is a schematic flowchart of a method for calibrating a battery level provided by another embodiment of the present application:

FIG. 4 is a schematic flowchart of a method for determining a turn-off type provided by an embodiment of the present application:

FIG. 5 is a schematic flowchart of a method for calibrating a battery level provided by yet another embodiment of the present application; and

FIG. 6 is a schematic structural diagram of an electronic device provided by an embodiment of the present application.

### DETAILED DESCRIPTION OF EMBODIMENTS

In the following description, for the purpose of explanation rather than limitation, specific details such as particular system structures and technologies are proposed to provide a thorough understanding of the embodiments of the present application. However, it will be apparent to persons of ordinary skills in the art that the present application may be practiced in other embodiments without these specific details. In other instances, detailed descriptions of well-known systems, devices, circuits, and methods are omitted so as not to obscure the description of the present application with unnecessary details.

It should be understood that, when used in this specification and the appended claims, the term “including/comprising” indicates the presence of the described features, integers, steps, operations, elements and/or components but does not exclude the presence or addition of one or more other features, integers, steps, operations, elements, components and/or any combination thereof.

It should also be understood that the term “and/or” used in this specification and the appended claims refers to any combination of one or more of the associated listed items and all possible combinations, and includes these combinations.

As used in this specification and the appended claims, the term “if” may be interpreted as “when” or “once” or “in response to a determination” or “in response to a detection” depending on the context. Similarly, the phrase “if determined” or “if [the described condition or event] is detected” may be interpreted, depending on the context, to mean “upon determining” or “in response to determining” or “once [the described condition or event] is detected]” or “in response to detecting [the described condition or event]”.

In addition, in the description of this specification and the appended claims, the terms “first”, “second”, “third”, etc. are only used to distinguish the description, and cannot be understood as indicating or implying relative importance.

The reference to “one embodiment” or “some embodiments” or the like described in this specification means that a particular feature, structure or characteristic described in connection with the embodiment is included in one or more embodiments of the present application. Therefore, the statements “in one embodiment,” “in some embodiments,” “in other embodiments,” “in further embodiments”, etc. appearing in different places in this specification do not necessarily all refer to the same embodiment, but rather to “one or more but not all embodiments” unless specifically stated otherwise. The terms “including,” “includes,” “having,” and variations thereof all mean “including but not limited to” unless otherwise specifically emphasized.

Currently, most electronic devices are powered by batteries, such as POS machines. In case that the electronic device is turned off, the battery is still supplying power to the coulometer and peripheral circuits in the electronic device, and the battery power is consumed quickly. For convenience of explanation, a POS machine is taken as an example for the electronic device in the present application in the following description.

For the POS machine, in case that the battery level is lower than a preset value, the security CPU in the POS machine will be triggered, causing the POS machine to enter a safe mode, as a result, the user is unable to use the POS machine after getting it.

Based on the above problem, in the present application, some configurations in the POS machine will be powered off in case that the POS is turned off, such as the coulometer, the peripheral circuit, etc., to reduce battery power consumption and prolong the battery lifespan.

In addition, since the coulometer is powered off and does not work in case that the POS machine is turned off, the data in the coulometer will be lost, thus, the POS machine needs to calibrate the battery level when the POS machine is turned on to ensure that the remaining battery level of the POS machine is accurate.

Based on the above problem, in the present application, the turn-off time and turn-off remaining battery level are saved before a turn-off operation, and the battery level in the POS machine is calibrated based on the turn-off time and the turn-off remaining battery level after the POS machine is turned on, to obtain an accurate battery level.

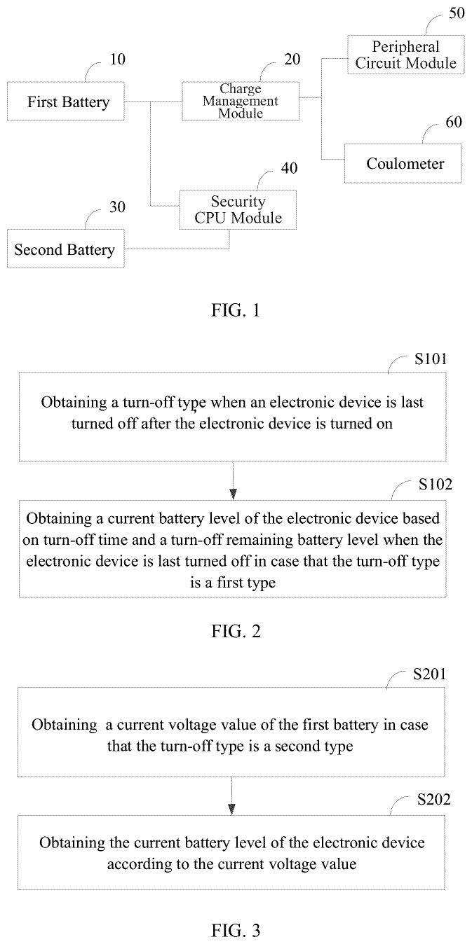

FIG. 1 shows a schematic structural diagram of an electronic device provided by the present application. Referring to FIG. 1, the electronic device includes: a first battery 10, a second battery 30, a charging management module 20, a security CPU module 40, a peripheral circuit module 50 and a coulometer 60. The peripheral circuit module 50 includes a processor. The security CPU module 40 includes a security CPU chip.

The first battery 10 is connected to the charging management module 20 and the security CPU module 40 respectively. The charging management module 20 is connected to the peripheral circuit module 50 and the coulometer 60 respectively. The second battery 30 is connected to the security CPU module 40.

The battery capacity of the first battery 10 is greater than the battery capacity of the second battery 30. For example, batteries in the first battery are No. 5 batteries, and batteries in the second battery are button batteries.

In this embodiment, when the electronic device is turned off or turned on, at least one of the first battery 10 and the second battery 30 supplies power to the security CPU module 40. Particularly, the first battery 10 may first supply power to the security CPU module 40, and after the battery power of the first battery 10 is lower than a preset value, the second battery 30 may be initiated to supply power to the security CPU module 40.

In a possible implementation, during operation of the electronic device, the processor is configured to detect a turn-off signal, where the turn-off signal is a signal generated by acting on a turn-off button or turn-off control of the electronic device. In the present application, the turn-off signal is recorded as a first signal. For example, the first signal is generated when a hard pressing is performed on the turn-off button.

The processor, in response to a detection of the turn-off signal, reads a value of the current battery level from the coulometer 60 and writes the value of the current battery level and the current time into the peripheral circuit module 50. A first instruction is sent to the charging management module 20 after the value of the current battery level and the current time are written into the peripheral circuit module 50, where the first instruction is used to instruct the charging management module to control the first battery to stop supplying power to the coulometer 60 and the peripheral circuit module 50.

Particularly, the peripheral circuit module 50 may also include a FLASH chip, and the processor writes the value of the current battery level and the current time into the FLASH chip.

Particularly, the value of the current battery level is used to represent the turn-off remaining battery level at this turn-off, and the current time is used to represent the turn-off time at this turn-off. At the next time the electronic device is turned on, the turn-off time in the FLASH chip is the turn-off time at the last turn-off, and the turn-off remaining battery level in the FLASH chip is the remaining battery level of the electronic device at the time of the last turn-off.

As an example, if the current time is 5:20 and the electronic device needs to be turned off, then the current time and the value of the current battery level will be stored by the processor into the FLASH chip. After 20 minutes, the current time is 5:40 and the electronic device is turned on. The time and the battery level value stored in the FLASH chip are the turn-off time and the turn-off remaining battery level at the turn-off time of 5:20.

In this embodiment, after the turn-off time and turn-off remaining battery level are written by the processor into the peripheral circuit module 50, the first instruction is sent by the processor to the charging management module 20. After the first instruction is received by the charging management module 20, the paths between the charging management module 20 and the peripheral circuit module 50, as well as the charging management module 20 and the coulometer 60 are disconnected by the charging management module 20, so that the first battery 10 does not supply power to the peripheral circuit module 50 and the coulometer 60 when the electronic device is turned off, which reduces battery consumption and prolongs the lifespan of the first battery.

As an example, if a total battery capacity of the POS machine is 2000 mAh, and the power consumption per unit time of the POS machine when being turned off is 20 uAh, then the time required to consume 1% of the power is: 1%=Y*20*100%/3600/2000000, Y=3,600,000 seconds=1,000 hrs=41.66 days. That is to say, when the POS machine is in a turn-off state, it takes more than 41 days to consume 1% of the power. If 60% (according to the POS machine storage standard) of the power is saved at the time the POS machine is turned off, then it will take 41.66*60=2499.6 days=about 6.8 years to consume 60% of the power. If the POS machine is fully charged with 2000 mAh, then the POS machine can be used for 41.66*100=4166 days=11.4 years when the POS machine is in the turn-off state, which meets the standard of POS machines being trigger-able without powered failure within 3 years.

In a possible implementation, since the first battery 10 continues to supply power to the charging management module 20 when the electronic device is turned off, the charging management module 20 can still continue to operate when the electronic device is turned off.

The charging management module 20 is also configured to detect a turn-on signal, where the turn-on signal is a signal generated by acting on a turn-on button of the electronic device, or a signal generated when an external power supply is plugged into the electronic device.

The charging management module 20, in response to a detection of the turn-on signal, switches on the paths between the charging management module 20 and the peripheral circuit module 50, as well as the charging management module 20 and the coulometer 60, so that the first battery 10 is enabled to supply power to the peripheral circuit module 50 and the coulometer 60 through the charging management module 20 to ensure that each device configurations can operate normally after the electronic device is turned on.

In a possible implementation, the processor may also be configured to detect a restart signal which is a signal generated by acting on a restart button or restart control of the electronic device. For example, the restart signal is generated when the restart button is pressed by a user.

The processor, in response to a detection of the restart signal, restarts the software in the electronic device, and the various hardware in the electronic device are not powered off. Particularly, during a restart process of the electronic device, the first battery 10 continues to supply power to the peripheral circuit module 50 and the coulometer 60 through the charging management module 20. Since the coulometer 60 is not powered off during the restart process and is always in operation, the coulometer 60 is enabled to calculate the current battery level of the electronic device in real time. Thus, the battery level shown in the coulometer 60 is the current battery level of the electronic device after the electronic device is turned on, and the battery level shown in the coulometer 60 does not need to be calibrated. In case that the electronic device is restarted, the processor will not control the peripheral circuit module 50 to store the turn-off time and the turn-off remaining battery level, as a result, the electronic device cannot read the turn-off time and the turn-off remaining battery level from the peripheral circuit module 50 when the electronic device is turned on if the turn-off of electronic device is caused by restart.

In a possible implementation, the charging management module 20 may include a register. The register is initialized when the power is off, and data in the register can be restored to initial data. In the present application, the data in the register is recorded as first data, and the initial data is recorded as a second default value. For example, the second default value may be 0, 2 or 4 etc.

The register is powered on when the electronic device is turned on, and the data in the register is still the second default value until a second instruction is sent by the processor to the charging management module 20. The charging management module 20, after receiving the second instruction, updates the initial data to a first default value, and the first default value indicates that the charging management module 20 is turned on. For example, the first default value may be 1, 3, or 5, etc.

During operation of the electronic device, if the charging management module 20 has no power failure, the data in the register of the charging management module 20 will remain unchanged at the first default value until the charging management module 20 is powered off then the data in the charging management module 20 is restored to the second default value.

In a possible implementation, the turn-off of the electronic device may be caused by the first battery being loose or removed (that causes the electronic device to be powered off). In case that the electronic device is turned off due to the looseness or removal of the first battery 10, then the processor does not store the turn-off time and the remaining turn-off power in the peripheral circuit module 50, thus, when the electronic device is turned on again, the processor cannot obtain the turn-off time and the turn-off remaining battery level at the last turn-off.

If the electronic device is turned off due to the looseness or removal of the first battery 10, then the charging management module 20, the peripheral circuit module 50 and the coulometer 60 in the electronic device are all powered off when the electronic device is turned off. The data in the charging management module 20 is restored to the second default value.

In case that the electronic device is turned on, the first data in the peripheral circuit module 50 may be read by the processor first, and then based on the first data, it may be determined by the processor whether the last turn-off is caused by the looseness or removal of the first battery.

Particularly, if the first data is the first default value, then it is determined that the last turn-off is not caused by the looseness or removal of the first battery 10. Particularly, first information in the peripheral circuit module 50 is obtained when it is determined that the last turn-off is not caused by the looseness or removal of the first battery 10, and based on the first information, it is determined whether the last turn-off is performed through the turn-off button or the turn-off control. If the first information includes the turn-off remaining battery level and the turn-off time, then it is determined that the last turn-off is performed through the turn-off button or the turn-off control. In the present application, the turn-off through the turn-off button or the turn-off control is recorded as a first type. If the first information does not include the turn-off remaining battery level and the turn-off time, then it is determined that the last turn-off is performed through the restart button or the restart control, in this case, the calibration of the battery level is not required.

In this embodiment, if the second data is the second default value, then it is determined that the last turn-off is caused by the loosening or removal of the first battery. In the present application, the turn-off due to the loosening or removal of the first battery is recorded as a second type.

In a possible implementation, the processor may implement the calibration of battery level in the following method for calibrating the battery level. For the specific process of battery level calibration, reference may be made to the following method for calibrating the battery level, which will not be described again here.

The method for calibrating the battery level in an embodiment of the present application will be described in detail below with reference to FIG. 1.

FIG. 2 shows a schematic flowchart of the method for calibrating the battery level provided by the present application. Referring to FIG. 2, the method is described in detail as follows:

In step S101, a turn-off type when an electronic device is last turned off is obtained after the electronic device is turned on.

In this embodiment, the electronic device is turned on refers to that the electronic device starts running. The turn-off type of the electronic device may include the turn-off of the electronic device due to an action on the turn-off button or the turn-off control, the turn-off of the electronic device due to an action on the restart button or the restart control, or the turn-off of the electronic device due to the loosening or removal of the first battery.

Particularly, if the electronic device is turned off due to the action on the turn-off button or turn-off control, in this case, the first battery supplies power to the charging management module but not to the peripheral circuit module and the coulometer after the electronic device is turned off, and this kind of turn-off is recorded as the first type.

If the electronic device is turned off due to the action on the restart button or restart control, in this case, the first battery always supplies power to the charging management module, peripheral circuit module and coulometer during the process from turn-off to restart of the electronic device. The battery level in the coulometer does not need to be calibrated.

If the electronic device is turned off due to the looseness or removal of the first battery, in this case, the first battery will not power the charging management module, the peripheral circuit module and the coulometer after the electronic device is turned off.

In step S102, a current battery level of the electronic device is obtained, in case that the turn-off type is a first type, based on turn-off time and a turn-off remaining battery level when the electronic device is last turned off.

In this embodiment, the first type includes that: the first battery supplies power to the charging management module but not to the peripheral circuit module and the coulometer after the electronic device is turned off.

Particularly, the turn-off time and turn-off remaining battery level are obtained from a FLASH chip in the peripheral circuit module.

Particularly, the implementation process of step S102 may include steps S1021 to S1023.

In step S1021, a first difference of the current time minus the turn-off time.

In step S1022, a first product of the first difference and a power consumption per unit time after turn-off is calculated.

In step S1023, the current battery level is obtained based on the first product, the turn-off remaining battery level, and a preset total capacity of the battery/batteries in the first battery.

In this embodiment, the total capacity of the batteries may be set according to the type of battery used. For example, the battery capacity of No. 7 battery is different from that of No. 5 battery.

In this embodiment, a first ratio of the first product and the total capacity is calculated to obtain the turn-off power consumption.

A second difference between the turn-off remaining battery level and the first ratio is calculated to obtain the current battery level.

Particularly, a power calculation model may be utilized to calculate the current battery level. The power calculation model includes:

$$U = {U}_{L} - \frac{( {T}_{D} - {T}_{L} ) \times {U}_{A}}{{U}_{total}} \times 100 \%$$

Where, U is the current battery level, U_{L} is the turn-off remaining battery level, T_{D} is the current time, T_{L} is the turn-off time, U_{A} is the power consumption per unit time after turn-off, and Uₜₒₜₐₗ is the total capacity.

In this embodiment, after the current battery level is obtained, the current battery level may be sent to the coulometer, so that the coulometer saves the current battery level and continues to calculate subsequent battery level according to the current battery level.

In this embodiment, after the current battery level is calculated, the remaining turn-off power and turn-off time in the FLASH chip in the peripheral circuit module may be erased to prevent the battery level from being calibrated after reading the turn-off time and turn-off remaining battery level during restart, resulting in inaccurate battery level of electronic device after restarting.

In this embodiment, after the current battery level is obtained, the system in the electronic device is officially started. Each power-consuming unit in the electronic device can read the current battery level and determine whether the current battery level meets its own power needs. If the current battery level can meet its own power needs, then the power-consuming unit can operate normally. If the current battery level does not meet its own power needs, then the power-consuming unit cannot operate normally.

As an example, the power-consuming unit may include a Bluetooth unit, a printing unit, etc.

In an embodiment of the present application, the turn-off type when the electronic device is last turned off is first obtained after the electronic device is turned on; and the current battery level of the electronic device is obtained, in case that the turn-off type is the first type, based on the turn-off time and the turn-off remaining battery level when the electronic device is last turned off, where the first type includes that: the first battery supplies power to the charging management module but not to the peripheral circuit module and coulometer after the electronic device is turned off. In the present application, the turn-off time and the turn-off remaining battery level at the last turn-off are utilized to obtain the current battery level, which is more accurate than the current battery level obtained by using the OCV curve in the existing technologies.

As shown in FIG. 3, in a possible implementation, after step 101, the above method may also include steps S201 and S202.

In step S201, a current voltage value of the first battery is obtained in case that the turn-off type is a second type.

In this embodiment, the second type includes that the first battery does not supply power to the peripheral circuit module, the charging management module and the coulometer after the electronic device is turned off.

In this embodiment, in case that the electronic device is turned off by removing the battery, the processor cannot predict in advance, thus, the peripheral circuit module cannot save the turn-off time and the turn-off remaining battery level during the turn-off. Thus, the current battery level cannot be calculated based on the turn-off time and the turn-off remaining battery level in case that the turn-off type is the second type.

After the electronic device is turned on and the coulometer is powered on, the coulometer is enabled to read the voltage value of the battery/batteries in the first battery. In the present application, the voltage value read by the coulometer is recorded as the current voltage value. The processor may obtain the current voltage value from the coulometer.

In step S202, the current battery level of the electronic device is obtained according to the current voltage value.

Particularly, a pre-stored OCV curve is obtained: a first battery level value corresponding to the current voltage value is found in the OCV curve, and the first battery level value is the current battery level of the POS machine.

In this embodiment, the OCV curve is a graph representing the relationship between voltage and battery level, and each voltage value in the curve corresponds to a battery level value.

In this embodiment, the current battery level is sent to the coulometer after the current battery level is obtained, and the coulometer performs subsequent electric quantity calculation based on the current battery level.

In the embodiment of the present application, the current voltage value and OCV curve of the battery are used to obtain the current battery level, which can ensure that the battery level can still be calibrated in case that the turn-off type is the second type and the turn-off time and turn-off remaining battery level cannot be obtained.

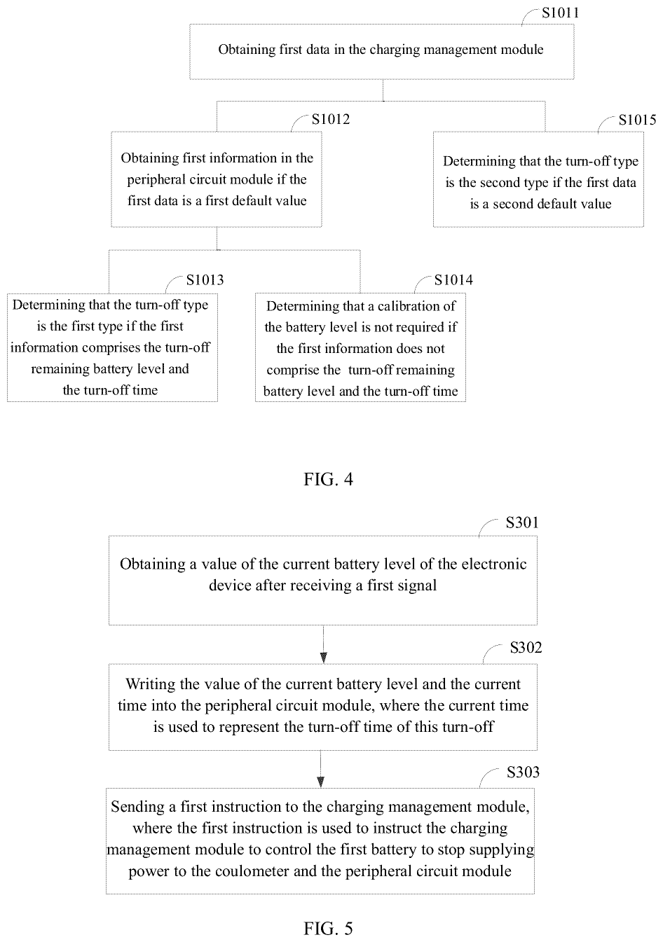

As shown in FIG. 4, in a possible implementation manner, the implementation process of step S101 may include steps S1011 to S1015.

In step S1011, first data in the charging management module is obtained.

In this embodiment, the first data in the charging management module is first read after the electronic device is turned on. Particularly, the first data is read from the register in the charging management module. Because during normal turn-off, the charging management module will not be powered off, i.e., is always powered on, and the power supply to the charging management module will be cut off only in case that the first battery is loose or removed, thus, a register can be arranged in the charging management module. In case that the charging management module is powered off, then the data in the register is restored to default data (initial data), that is the second default value. In case that the charging management module is turned on, then the processor may control the second default value in the register to be updated to the first default value. Based on the above configurations, the first data can be read from the register, after the electronic device is turned on, and the turn-off type at the last turn-off can be determined based on the first data.

In this embodiment, the normal turn-off is to turn off the device by pressing the turn-off button or the turn-off control, or pressing the restart button or the restart control.

In step S1012, first information in the peripheral circuit module is obtained if the first data is a first default value.

In this embodiment, the first default value indicates that the charging management module is in a power-on state before the electronic device is turned on.

In this embodiment, it may be determined that the last turn-off is a normal turn-off and the charging management module is not powered off after the last turn-off if the first data is the first default value.

In step S1013, it is determined that the turn-off type is the first type if the first information includes the turn-off remaining battery level and the turn-off time.

In step S1014, a calibration of the battery level is not required if the first information does not include the turn-off remaining battery level and the turn-off time.

In this embodiment, the battery level needs to be calibrated only when the turn-off button or the turn-off control is pressed. If the last turn-off is caused by pressing the restart button or the restart control, since the coulometer continues to be powered on in this case, the calibrate the battery level is not required.

Thus, it is also necessary to determine whether the last turn-off is a turn-off caused by pressing the turn-off button or the turn-off control after determining that the last turn-off is a normal turn-off.

In this embodiment, as the turn-off time and the turn-off remaining battery level are already stored in the peripheral circuit module during turn-off when the turn-off is performed by pressing the turn-off button or the turn-off control, thus, it can be determined whether the last turn-off is a turn-off caused due to the action on the turn-off button or turn-off control according to whether the turn-off time and the turn-off remaining battery level is presented in the peripheral circuit. If the first information includes the turn-off remaining battery level and the turn-off time, then it is determined that the turn-off type is the first type.

In step S1015, it is determined that the turn-off type is a second type if the first data is a second default value.

In this embodiment, the second default value indicates that the charging management module is in a power-off state before the electronic device is turned on.

In this embodiment, since the first data in the charging management module is updated to the second default value after the charging management module is powered off, then it is first determined whether the turn-off type is the second type based on the data in the charging management module after the electronic device is turned on. If the first data is the second default value, then it is determined that the turn-off type is the second type.

In this embodiment, a second instruction is sent by the processor to the charging management module after the turn-off type is determined. The charging management module, after receiving the second instruction, updates the second default value to the first default value and maintains the first default value unchanged until the charging management module is powered off, then, the first default value in the charging management module is changed to the second default value.

As shown in FIG. 5, in a possible implementation, the above method may also include steps S301 to S303.

In step S301, a value of the current battery level of the electronic device is obtained after the first signal is received.

In this embodiment, the first signal is a signal generated by acting on the turn-off button or turn-off control of the electronic device.

In this embodiment, the value of the current battery level is used to represent the turn-off remaining battery level of the electronic device at this turn-off, that is, the remaining battery level of the electronic device when the electronic device is turned off this time.

Particularly, the value of the current battery level of the electronic device is obtained from the coulometer.

In step S302, the value of the current battery level and the current time are written into the peripheral circuit module, where the current time is used as the turn-off time of this turn-off.

In step S303, a first instruction is sent to the charging management module. The first instruction is used to instruct the charging management module to control the first battery to stop supplying power to the coulometer and peripheral circuit module.

Particularly, the first instruction is sent to the charging management module after the value of the current battery level and the current time are written into the peripheral circuit module.

In an embodiment of the present application, before the electronic device is turned off, the current time and value of the current battery level are saved in the peripheral circuit module, so that the next time the device is turned on, the battery level can be calibrated based on the turn-off time and turn-off remaining battery level saved at the last turn-off.

In a possible implementation, the above method may also include steps S401 to S410.

In step S401, the first data in the register of the charging management module is obtained.

In step S402, the first information in the FLASH chip of the peripheral circuit module is obtained if the first data is the first default value.

In step S403, it is determined that the turn-off type is the first type if the first information includes the turn-off remaining battery level and the turn-off time. The current battery level of the electronic device is obtained based on the turn-off time and turn-off remaining battery level when the electronic device is last powered off. The first type includes that the first battery supplies power to the charging management module but not to the peripheral circuit module and the coulometer after the electronic device is turned off. After calculation, the first instruction is sent to the charging management module. The first instruction is used to instruct the charging management module to control the first battery to stop supplying power to the peripheral circuit module and the coulometer.

In step S404, a calibration for battery level is not required if the first information does not include the turn-off remaining battery level and the turn-off time.

In step S405, it is determined the turn-off type is the second type if the first data is the second default value. The current voltage value of the first battery read by the coulometer is obtained. The second type includes that the first battery does not supply power to the peripheral circuit module, the charging management module and the coulometer after the electronic device is turned off.

In step S406, the current battery level of the electronic device is obtained according to the current voltage value.

In step S407, the current battery level is sent to the coulometer.

In step S408, a turn-off signal is obtained and it is determined whether the turn-off signal is a signal generated by pressing the turn-off button.

In step S409, a value of the current battery level of the coulometer is read, and the current time and the value of the current battery level are saved in the FLASH chip if the turn-off signal is the signal generated by pressing the turn-off button.

In step S410, the electronic device is turned off.

It should be understood that the sequence number of each step in the above embodiment does not mean the order of execution. The execution order of each process should be determined by its function and internal logic, and should not constitute any limitation on the implementation process of the embodiment of the present application.

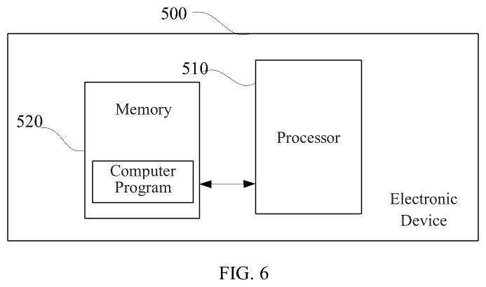

An embodiment of the present application also provides an electronic device. Referring to FIG. 6, the electronic device 500 may include: at least one processor 510, a memory 520, and a computer program stored in the memory 520 and executable by the at least one processor 510. The processor 510, when executing the computer program, is configured to implement the steps in any of the above method embodiments, such as steps S101 to S102 in the embodiment shown in FIG. 2.

For example, the computer program may be divided into one or more modules/units, and the one or more modules/units are stored in the memory 520 and executed by the processor 510 to implement the technical schemes of the present application. The one or more modules/units may be a series of computer program segments capable of implementing specific functions. The program segments are used to describe the execution process of the computer program in the electronic device 500.

It can be understood by persons of ordinary skills in the art that FIG. 6 is only an example of an electronic device and does not constitute any limitations on the electronic device. The electronic device may include more or fewer components than shown in the figure, or combine certain components, or different components, such as input and output devices, network access devices, buses, etc.

The processor 510 may be a central processing unit (CPU), or may be other general-purpose processors, a digital signal processor (DSP), an application specific integrated circuit (ASIC), or a field-programmable gate array (FPGA) or other programmable logic devices, discrete gates or transistor logic devices, discrete hardware components, etc. A general-purpose processor may be a microprocessor or the processor may be any conventional processor, etc.

The memory 520 may be an internal storage unit of the electronic device or an external storage device of the electronic device, such as a plug-in hard drive, a smart media card (SMC), a secure digital (SD) card, or a flash card etc. The memory 520 is used to store the computer program and other programs and data required by the electronic device. The memory 520 may also be used to temporarily store data that has been output or is to be output.

The bus may be an industry standard architecture (ISA) bus, a peripheral component interconnect (PCI) bus, or an extended industry standard architecture (EISA) bus, etc. The bus may be divided into an address bus, a data bus, a control bus, etc. For ease of presentation, the bus in the drawings of the present application is not limited to only one bus or one type of bus.

The method for calibrating the battery level provided by the embodiments of the present application may be applied to terminal equipment such as a computer, a tablet, a laptop, a netbook, a personal digital assistant (PDA), etc. The embodiments of the present application do not place any restrictions on the specific type of terminal equipment.

In the above embodiments, each embodiment is described with its own emphasis. For parts that are not detailed or documented in a certain embodiment, references may be made to the relevant descriptions of other embodiments.

It will be appreciated by persons of ordinary skills in the art that the units and algorithm steps of each example described in conjunction with the embodiments disclosed herein may be implemented with electronic hardware, or a combination of computer software and electronic hardware. Whether these functions are performed in hardware or software depends on the specific application and design constraints of the technical scheme. Skilled artisans may implement the described functionality using different methods for each specific application, but such implementations should not be considered beyond the scope of the present application.

In the embodiments provided in the present application, it should be understood that the disclosed terminal equipment, devices and methods may be implemented in other ways. For example, the terminal equipment embodiments described above are only illustrative. For example, the division of modules or units is only a logical function division. In actual implementation, other division methods may be possible, such as multiple units or components may be combined or may be integrated into another system, or some features may be ignored, or not implemented. On the other hand, the coupling or direct coupling or communication link between each other shown or discussed may be the indirect coupling or communication link of devices or units through some interfaces, or may be realized in electrical, mechanical or other forms.

The units described as separate components may or may not be physically separated, and the components shown as units may or may not be physical units, that is, these units or components may be located in one place, or may be distributed to multiple network units. Some or all of the units may be selected according to actual needs to achieve the purpose of the scheme of the embodiment.

In addition, each functional unit in each embodiment of the present application may be integrated into one processing unit, each unit may exist physically alone, or two or more units may be integrated into one unit. The above integrated units may be implemented in the form of hardware or software functional units.

The integrated unit, if implemented in the form of software functional units and sold or used as an independent product, may be stored in a computer-readable storage medium. Based on this understanding, the present application can implement all or part of the processes in the methods of the above embodiments, which may also be implemented by instructing relevant hardware through a computer program. The computer program may be stored in a computer-readable storage medium, and the computer program, when executed by one or more processors, enables the steps of each of the above method embodiments to be implemented.

Similarly, as a computer program product, the computer program product, when running on a piece of terminal equipment, causes the terminal equipment to implement the steps in each of the above method embodiments.

Among them, the computer program includes a computer program code, which may be in the form of source code, object code, executable file or some intermediate form. The computer-readable medium may include any entity or device capable of carrying the computer program code, a recording medium, U disk, a mobile hard disk, a magnetic disk, an optical disk, a computer memory, a read-only memory (ROM), a random access memory (RAM), an electrical carrier signal, a telecommunications signal, and a software distribution medium, etc. It should be noted that the content contained in the computer-readable medium may be appropriately added or deleted according to the requirements of legislation and patent practice in the jurisdiction. For example, in some jurisdictions, according to legislation and patent practice, the computer-readable medium excludes electrical carrier signals and telecommunications signals.

The above embodiments are only used to illustrate rather than limiting the technical schemes of the present application. Although the present application has been described in detail with reference to the foregoing embodiments, it should be understood by persons of ordinary skills in the art that the technical schemes described in the foregoing embodiments may still be modified, or some of the technical features in the foregoing embodiments may be equivalently substituted. These modifications or substitutions do not cause the essence of the corresponding technical schemes to deviate from the spirit and scope of the technical schemes of the embodiments of the present application, and thus shall all be included within the protection scope of the present application.

1. A method for calibrating a battery level, applied to an electronic device, the electronic device comprising a first battery, a charging management module, a peripheral circuit module and a coulometer for monitoring the battery level of the electronic device, the first battery supplying power to the coulometer and the peripheral circuit module through the charging management module after the electronic device is turned on; and
the method comprising:
obtaining a turn-off type when the electronic device is last turned off after the electronic device is turned on; and
obtaining a current battery level of the electronic device based on turn-off time and a turn-off remaining battery level when the electronic device is last turned off in case that the turn-off type is a first type, wherein the first type comprises that the first battery supplies power to the charging management module but not to the peripheral circuit module and the coulometer after the electronic device is turned off.

2. The method for calibrating the battery level according to claim 1, wherein after the obtaining the turn-off type when the electronic device is last turned off, the method further comprises:
obtaining a current voltage value of the first battery in case that the turn-off type is a second type, wherein the second type comprises that the first battery does not supply power to the peripheral circuit module, the charging management module and the coulometer after the electronic device is turned off; and
obtaining the current battery level of the electronic device according to the current voltage value.

3. The method for calibrating the battery level according to claim 2, wherein the obtaining the turn-off type when the electronic device is last turned off comprises:
obtaining first data in the charging management module;
obtaining first information in the peripheral circuit module if the first data is a first default value, wherein the first default value indicates that the charging management module is in a power-on state before the electronic device is turned on;
determining that the turn-off type is the first type if the first information comprises the turn-off remaining battery level and the turn-off time; and
determining that a calibration of the battery level is not required if the first information does not comprise the turn-off remaining battery level and the turn-off time.

4. The method for calibrating the battery level according to claim 3, wherein after the obtaining the first data in the charging management module, the method further comprises:
determining that the turn-off type is the second type if the first data is a second default value, wherein the second default value indicates that the charging management module is in a power-off state before the electronic device is turned on.

5. The method for calibrating the battery level according to claim 1, wherein the obtaining the current battery level of the electronic device based on the turn-off time and the turn-off remaining battery level when the electronic device is last turned off comprises:
determining a first difference by subtracting the turn-off time from a current time;
determining a first product of the first difference and a power consumption per unit time after turn-off;
obtaining the current battery level based on the first product, the turn-off remaining battery level and a preset total capacity of the first battery.

6. The method for calibrating the battery level according to claim 2, wherein the obtaining the current battery level of the electronic device according to the current voltage value comprises:
getting a pre-stored OCV curve;
finding a first battery level value corresponding to the current voltage value in the pre-stored OCV curve, wherein the first battery level value is a value of the current battery level of the electronic device.

7. The method for calibrating the battery level according to claim 1, wherein the method further comprises:
obtaining a value of the current battery level of the electronic device after receiving a first signal, wherein the first signal is a signal generated by acting on a turn-off button or a turn-off control of the electronic device, and the value of the current battery level is used to indicate the turn-off remaining battery level of the electronic device at this turn-off;
writing the value of the current battery level and a current time into the peripheral circuit module, wherein the current time is used to represent the turn-off time of this turn-off; and
sending a first instruction to the charging management module, wherein the first instruction is used to instruct the charging management module to control the first battery to stop supplying power to the coulometer and the peripheral circuit module.

8. The method for calibrating the battery level according to claim 1, wherein the electronic device further comprises a second battery and a security CPU module; the first battery and the second battery are both connected to the security CPU module, and at least one of the first battery and the second battery supplies power to the security CPU module when the electronic device is turned off or turned on.

9. An electronic device, comprising: a first battery, a charging management module, a peripheral circuit module and a coulometer for monitoring a battery level of the electronic device, the first battery supplying power to the coulometer and the peripheral circuit module through the charging management module after the electronic device is turned on, and the peripheral circuit module comprising a processor; and
wherein the processor is configured to implement operations that comprise:
obtaining a turn-off type when the electronic device is last turned off after the electronic device is turned on; and
obtaining a current battery level of the electronic device based on turn-off time and a turn-off remaining battery level when the electronic device is last turned off in case that the turn-off type is a first type, wherein the first type comprises that the first battery supplies power to the charging management module but not to the peripheral circuit module and the coulometer after the electronic device is turned off.

10. A non-transitory computer-readable storage medium in which a computer program is stored, wherein the computer program, when executed by a processor, enables the processor to perform operations that comprise:
obtaining a turn-off type when an electronic device is last turned off after the electronic device is turned on, wherein the electronic device comprises a first battery, a charging management module, a peripheral circuit module and a coulometer for monitoring a battery level of the electronic device, the first battery supplies power to the coulometer and the peripheral circuit module through the charging management module after the electronic device is turned on; and
obtaining a current battery level of the electronic device based on turn-off time and a turn-off remaining battery level when the electronic device is last turned off in case that the turn-off type is a first type, wherein the first type comprises that the first battery supplies power to the charging management module but not to the peripheral circuit module and the coulometer after the electronic device is turned off.

11. The electronic device according to claim 9, wherein after the obtaining the turn-off type when the electronic device is last turned off, the operations further comprise:
obtaining a current voltage value of the first battery in case that the turn-off type is a second type, wherein the second type comprises that the first battery does not supply power to the peripheral circuit module, the charging management module and the coulometer after the electronic device is turned off; and
obtaining the current battery level of the electronic device according to the current voltage value.

12. The electronic device according to claim 11, wherein the operation of obtaining the turn-off type when the electronic device is last turned off comprises:
obtaining first data in the charging management module;
obtaining first information in the peripheral circuit module if the first data is a first default value, wherein the first default value indicates that the charging management module is in a power-on state before the electronic device is turned on;
determining that the turn-off type is the first type if the first information comprises the turn-off remaining battery level and the turn-off time; and
determining that a calibration of the battery level is not required if the first information does not comprise the turn-off remaining battery level and the turn-off time.

13. The electronic device according to claim 12, wherein after the obtaining the first data in the charging management module, the operations further comprise:
determining that the turn-off type is the second type if the first data is a second default value, wherein the second default value indicates that the charging management module is in a power-off state before the electronic device is turned on.

14. The electronic device according to claim 9, wherein the operation of obtaining the current battery level of the electronic device based on the turn-off time and the turn-off remaining battery level when the electronic device is last turned off comprises:
determining a first difference by subtracting the turn-off time from a current time;
determining a first product of the first difference and a power consumption per unit time after turn-off;
obtaining the current battery level based on the first product, the turn-off remaining battery level and a preset total capacity of the first battery.

15. The electronic device according to claim 11, wherein the operation of obtaining the current battery level of the electronic device according to the current voltage value comprises:
getting a pre-stored OCV curve;
finding a first battery level value corresponding to the current voltage value in the pre-stored OCV curve, wherein the first battery level value is a value of the current battery level of the electronic device.

16. The electronic device according to claim 9, wherein the operations further comprise:
obtaining a value of the current battery level of the electronic device after receiving a first signal, wherein the first signal is a signal generated by acting on a turn-off button or a turn-off control of the electronic device, and the value of the current battery level is used to indicate the turn-off remaining battery level of the electronic device at this turn-off;
writing the value of the current battery level and a current time into the peripheral circuit module, wherein the current time is used to represent the turn-off time of this turn-off; and
sending a first instruction to the charging management module, wherein the first instruction is used to instruct the charging management module to control the first battery to stop supplying power to the coulometer and the peripheral circuit module.

17. The electronic device according to claim 9, wherein the electronic device further comprises a second battery and a security CPU module; the first battery and the second battery are both connected to the security CPU module, and at least one of the first battery and the second battery supplies power to the security CPU module when the electronic device is turned off or turned on.

18. The non-transitory computer-readable storage medium according to claim 10, wherein after the obtaining the turn-off type when the electronic device is last turned off, the operations further comprise:
obtaining a current voltage value of the first battery in case that the turn-off type is a second type, wherein the second type comprises that the first battery does not supply power to the peripheral circuit module, the charging management module and the coulometer after the electronic device is turned off; and
obtaining the current battery level of the electronic device according to the current voltage value.

19. The non-transitory computer-readable storage medium according to claim 18, wherein the operation of obtaining the turn-off type when the electronic device is last turned off comprises:
obtaining first data in the charging management module;
obtaining first information in the peripheral circuit module if the first data is a first default value, wherein the first default value indicates that the charging management module is in a power-on state before the electronic device is turned on;
determining that the turn-off type is the first type if the first information comprises the turn-off remaining battery level and the turn-off time; and
determining that a calibration of the battery level is not required if the first information does not comprise the turn-off remaining battery level and the turn-off time.

20. The non-transitory computer-readable storage medium according to claim 19, wherein after the obtaining the first data in the charging management module, the operations further comprise:
determining that the turn-off type is the second type if the first data is a second default value, wherein the second default value indicates that the charging management module is in a power-off state before the electronic device is turned on.
